(19) United States
(12) Patent Application Publication
(10) Pub. No.: US 2011/0284523 A1
(43) Pub. Date: Nov. 24, 2011

(54) METHOD FOR MANUFACTURING THERMOELECTRIC CONVERSION MODULE

(75) Inventors: Yuichi Hiroyama, Ibaraki (JP); Kazuo Sadaoka, Osaka (JP); Yoshinari Sawabe, Ibaraki (JP)

(73) Assignee: SUMITOMO CHEMICAL COMPANY, LIMITED, Chuo-ku, Tokyo (JP)

(21) Appl. No.: 13/144,725

(22) PCT Filed: Jan. 8, 2010
(86) PCT No.: PCT/JP2010/050160

§ 371 Date: Aug. 10, 2011

(30) Foreign Application Priority Data
Jan. 15, 2009 (JP) 2009006764

(51) Int. Cl. H01L 35/34

(52) U.S. Cl. 219/603

(57) ABSTRACT

There is provided a method for manufacturing a thermoelectric conversion module that allows adhesiveness between a thermoelectric conversion element and an electrode to be further increased. It is a method for manufacturing a thermoelectric conversion module 1 that comprises a step of bonding thermoelectric conversion elements 10 to electrodes 6, 8 by electromagnetic induction heating of the thermoelectric conversion elements 10.

### TECHNICAL FIELD

The present invention relates to a method for manufacturing a thermoelectric conversion module.

### BACKGROUND ART

As a method for bonding an electrode to a thermoelectric conversion element during the fabrication of a thermoelectric conversion module, Patent document 1, for example, describes a method in which an induction-heated jig is used for heating and pressing of electrodes and a plurality of thermoelectric conversion elements onto a substrate from the side opposite the face of the substrate on which the electrode has been formed.

Also, Patent document 2 discloses a method in which a bonding metal layer comprising a ferromagnetic material is provided between a metal circuit and semiconductor element formed on a circuit board, and the bonding metal layer is subjected to electromagnetic induction heating to bond the semiconductor element onto the circuit board.

### CITATION LIST

### Patent Literature

[Patent document 1] JP5-013660U
[Patent document 2] JP2008-112955A

### SUMMARY OF INVENTION

### Technical Problem

With the method of Patent document 1, however, the adhesiveness between thermoelectric conversion elements and electrodes has not been sufficient. Applying the method of Patent document 2 to thermoelectric conversion modules has also resulted in insufficient adhesiveness between thermoelectric conversion elements and electrodes.

The present invention therefore provides a method for manufacturing a thermoelectric conversion module that can increase the adhesiveness between thermoelectric conversion elements and electrodes.

### Solution to Problem

The method for manufacturing a thermoelectric conversion module according to the invention comprises a step of bonding a thermoelectric conversion element to an electrode by electromagnetic induction heating of the thermoelectric conversion element.

According to the invention, direct electromagnetic induction heating of the thermoelectric conversion element can easily bring the thermoelectric conversion element to a high temperature and increase the adhesiveness between the thermoelectric conversion element and the electrode.

The thermoelectric conversion element preferably comprises a ferromagnetic material and/or a ferrimagnetic material.

Because a ferromagnetic material and/or a ferrimagnetic material has high magnetic permeability, it produces greater heat upon electromagnetic induction heating. If the thermoelectric conversion element contains a ferromagnetic material, therefore, the thermoelectric conversion element itself generates heat more readily and the adhesiveness between the thermoelectric conversion element and the electrode can be further increased.

In the manufacturing method of the invention, the thermoelectric conversion element is subjected to electromagnetic induction heating with the thermoelectric conversion element being in contact with the electrode, until a contact region melts in which the surface of the electrode is in contact with the thermoelectric conversion element.

By electromagnetic induction heating the thermoelectric conversion element until the region melts in which the electrode surface is to be bonded with the thermoelectric conversion element, it is possible to further increase the adhesiveness between the thermoelectric conversion element and the electrode.

In addition, the thermoelectric conversion element and the electrode can be bonded to each other by a binder by electromagnetic induction heating the thermoelectric conversion element with the binder interposed between the thermoelectric conversion element and the electrode, which is preferred.

The heat generated from the thermoelectric conversion element by electromagnetic induction heating of the thermoelectric conversion element causes melting the binder interposed between the thermoelectric conversion element and the electrode, thereby allowing the adhesiveness between the thermoelectric conversion element and the binder to be further increased.

Also, the thermoelectric conversion element preferably has a metal layer on a face of the surface of the thermoelectric conversion element, the face facing the electrode, and the metal layer preferably contains a ferromagnetic material and/or a ferrimagnetic material.

By bonding the electrode to the metal layer provided on the face of the surface of the thermoelectric conversion element facing the electrode, it is possible to further increase the adhesiveness between the thermoelectric conversion element and the electrode. Furthermore, since the metal layer contains a ferromagnetic material and/or a ferrimagnetic material, the metal layer, in addition to the thermoelectric conversion element, also generates heat upon electromagnetic induction heating, and the adhesiveness between the electrode and the thermoelectric conversion element can thus be further increased.

### Advantageous Effects of Invention

According to the invention it is possible to provide a method for manufacturing a thermoelectric conversion module that can further increase adhesiveness between thermoelectric conversion elements and the electrodes.

### BRIEF DESCRIPTION OF DRAWINGS

FIG. 1 is a cross-sectional view of one example of a thermoelectric conversion module 1 produced by a first embodiment of the invention.

FIG. 2 is a cross-sectional view of one example of a thermoelectric conversion module 1 produced by a second embodiment of the invention.

FIG. 3 is a cross-sectional view of one example of a thermoelectric conversion module 1 produced by a third embodiment of the invention.

### DESCRIPTION OF EMBODIMENTS

Preferred embodiments of the invention will now be explained in detail, with reference to the accompanying drawings. Throughout the explanation of the drawings, identical or corresponding elements will be referred to by the same reference numerals and will be explained only once. Also, the dimensional proportions in the drawings do not necessarily match the actual dimensional proportions.

A thermoelectric conversion module produced by a first embodiment will be explained first.

### First Embodiment

### (Thermoelectric Conversion Module)

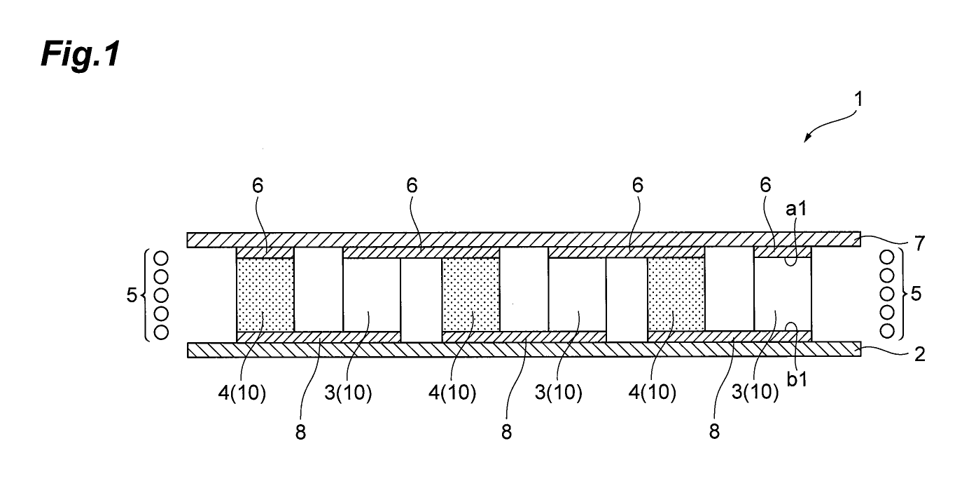

FIG. 1 is a cross-sectional view of one example of the thermoelectric conversion module 1 produced by the first embodiment. The thermoelectric conversion module 1 produced in this embodiment comprises a first substrate 2, first electrodes 8, p-type thermoelectric conversion elements 3 and n-type thermoelectric conversion elements 4 as thermoelectric conversion elements 10, second electrodes 6 and a second substrate 7. The p-type thermoelectric conversion elements 3 and the n-type thermoelectric conversion elements 4 are arranged alternately between the first substrate 2 and the second substrate 7, while both faces of them are connected to the corresponding surfaces of the first electrodes 8 and the second electrodes 6 in electrically series as a whole.

The first substrate 2 has a rectangular shape, for example, and is electrically insulating and thermally conductive, while covering one each of the ends of the plurality of thermoelectric conversion elements 10. The material of the first substrate may be, for example, alumina, aluminum nitride, magnesia, silicon carbide, zirconia, mullite or the like.

The first electrodes 8 are provided on the first substrate 2, and electrically connect one end sides of the mutually adjacent thermoelectric conversion elements 10. The first electrodes 8 may be formed on prescribed locations on the first substrate 2 by a thin-film technique such as sputtering or vapor deposition, or a method such as screen printing, plating or thermal spraying. Also, a metal sheet with a prescribed shape may be bonded onto the first substrate 2 by soldering, brazing or the like. The material for the first electrodes 8 is not particularly restricted so long as it is conductive, but from the viewpoint of improving heat resistance and corrosion resistance of the electrodes and adhesion onto the thermoelectric conversion elements, it is preferably a metal whose main component is one or more elements selected from the group consisting of titanium, vanadium, chromium, manganese, iron, cobalt, nickel, copper, molybdenum, silver, palladium, gold, tungsten and aluminum. Here, “main component” means a component present at 50 vol % or greater in the electrode material.

The second substrate 7 has a rectangular shape, for example, and covers the other end sides of the thermoelectric conversion elements 10. The second substrate 7 is laid facing and parallel to the first substrate 2. The second substrate 7 is not particularly restricted so long as it is electrically insulating and thermally conductive, similar to the first substrate 2, and a material such as alumina, aluminum nitride, magnesia, silicon carbide, zirconia or mullite, for example, may be used.

The second electrodes 6 electrically connect the other end sides of the mutually adjacent thermoelectric conversion elements 10 to each other, and they may be formed on the underside of the second substrate 7 by a thin-film technique such as sputtering or vapor deposition or a method such as screen printing, plating or thermal spraying. Also, the thermoelectric conversion elements 10 are electrically connected in series by the second electrodes 6 and the first electrodes 8 provided on the lower end face sides of the thermoelectric conversion elements 10.

The thermoelectric conversion elements 10 have two types of elements, a p-type thermoelectric conversion element 3 and an n-type thermoelectric conversion element 4. The material of each of the thermoelectric conversion elements 10 is not particularly restricted so long as it has a p-type semiconductor or n-type semiconductor property, and various materials such as metals or metal oxides may be used. A thermoelectric conversion element having a semiconductor property creates a current to generate heat when an alternative magnetic field is applied. In the method for manufacturing a thermoelectric conversion module described hereunder, this function, i.e. “electromagnetic induction heating” of the thermoelectric conversion elements 10, causes direct heating of the thermoelectric conversion elements, thereby accomplishing bonding between the thermoelectric conversion elements 10 and the first electrodes 8 (hereunder also referred to simply as “electrodes 6, 8”) on the first substrate 2. From the viewpoint of accomplishing efficient electromagnetic induction heating of the thermoelectric conversion elements, the thermoelectric conversion elements are preferably materials with high resistivity or magnetic permeability.

Materials for the p-type thermoelectric conversion elements and the n-type thermoelectric conversion elements include the following. Examples of p-type materials include mixed metal oxides such as NaₓCoO₂ (0<x<1) and Ca₃CO₄O₉, silicides such as MnSi_{1.73}, Fe₁₋ₓMnₓSi₂, Si_{0.8}Ge_{0.2}:B (B-doped Si_{0.8}Ge_{0.2}) and β-FeSi₂, skutterudites such as CoSb₃, FeSb₃, RFe₃CoSb₁₂ (where R represents La, Ce or Yb), Te-containing alloys such as BiTeSb, PbTeSb, Bi₂Te₃, PbTe and Sb₂Te₃, and Zn₄Sb₃.

Examples of n-type materials include mixed metal oxides such as SrTiO₃, Zn₁₋ₓ,AlₓO, CaMnO₃, LaNiO₃, BaTiO₃ and Tiₗ₋ₓNbₓO, silicides such as Mg₂Si, Fe₁₋ₓ,COₓSi₂, Si_{0.8}Ge_{0.2}:P(P-doped Si_{0.8}Ge_{0.2}) and β-FeSi₂, skutterudites such as CoSb₃, clathrate compounds such as Ba₈Al₁₂Si₃₀, Ba₈AlₓSi₄₆₋ₓ, Ba₈Al₁₂Ge₃₀ and Ba₈AlₓGe₄₆₋ₓ, boron compounds such as CaB₆, SrB₆, BaB₆ and CeB₆, Te-containing alloys such as BiTeSb, PbTeSb, Bi₂Te₃, Sb₂Te₃ and PbTe, and Zn₄Sb₃.

Considering that thermoelectric conversion modules may be used at temperatures of 300° C. and higher, the p-type thermoelectric conversion elements and the n-type thermoelectric conversion elements preferably comprise a metal oxide as the main component in the material, from the viewpoint of heat resistance and oxidation resistance. Among metal oxides, preferably the p-type material is Ca₃CO₄O₉ and the n-type material is CaMnO₃. Ca₃CO₄O₉ and CaMnO₃ have particularly excellent oxidation resistance in high-temperature air atmospheres, as well as high thermoelectric conversion performance.

From the viewpoint of subjecting the thermoelectric conversion elements 10 to sufficient high temperature by electromagnetic induction heating due to increasing the magnetic permeability in the step of bonding the thermoelectric conversion elements with the electrodes described hereunder, the thermoelectric conversion elements 10 preferably contain a magnetic material and/or a ferrimagnetic material.

Examples of ferromagnetic materials include iron, cobalt, nickel and gadolinium. Examples of ferrimagnetic materials include FeO. Fe₂O₃, MnO. Fe₂O₃, NiO. Fe₂O₃, CoO. Fe₂O₃ and Y₃Fe₅O₁₂ (YIG). Considering that thermoelectric conversion modules may be used at temperatures of 300° C. and higher, oxides are preferred as ferromagnetic materials and/or ferrimagnetic materials from the viewpoint of heat resistance and oxidation resistance.

There are no particular restrictions on the existence form of the ferromagnetic material and/or the ferrimagnetic material in the thermoelectric conversion elements 10, and it may be dispersed in the thermoelectric conversion elements or present as a layer in the thermoelectric conversion elements or on the side of the thermoelectric conversion elements. There are also no particular restrictions on the concentration of ferromagnetic materials and ferrimagnetic materials in the thermoelectric conversion elements, but it is preferably 10-50 wt %.

A method for manufacturing a thermoelectric conversion module according to this embodiment will now be described in detail.

### (Method for Manufacturing Thermoelectric Conversion Module)

The method for manufacturing a thermoelectric conversion module according to this embodiment comprises a) a step of preparing thermoelectric conversion elements, b) a step of forming electrodes and c) a step of bonding the thermoelectric conversion elements to the electrode.

a) Thermoelectric Conversion Element Preparation Step

A p-type thermoelectric conversion element and an n-type thermoelectric conversion element are prepared comprising the materials mentioned above as constituent components. The shapes of the thermoelectric conversion element bodies are not particularly restricted, and for example, they may be hexahedrons such as rectangular solids as shown in FIG. 1, or discs. The method for fabricating the p-type thermoelectric conversion element and the n-type thermoelectric conversion element will differ depending on the material composing the thermoelectric conversion elements, and for example, if the constituent material is an alloy the bulk alloy may be cut into the desired shapes to form the thermoelectric conversion elements. If the constituent material is a metal oxide, for example, a compound containing a metal element which is to compose the metal oxide may be mixed and sintered in an oxygen-containing atmosphere, and the obtained sintered material is cut and then formed into the desired shape to obtain a thermoelectric conversion element.

Either or both of the p-type thermoelectric conversion element and the n-type thermoelectric conversion element preferably comprises a ferromagnetic material and/or a ferrimagnetic material, as mentioned above. For example, a powder as the starting material for the thermoelectric conversion element and a powdered ferromagnetic material and/or a powdered ferrimagnetic material may be mixed and sintered in an oxygen-containing atmosphere or in an inert atmosphere, and the obtained sintered material is cut and then formed into the desired shape to obtain a thermoelectric conversion element containing the ferromagnetic material and/or the ferrimagnetic material. Alternatively, the starting material for the ferromagnetic material and/or the ferrimagnetic material, containing a constituent element of the ferromagnetic material and/or the ferrimagnetic material, may be mixed with a powder as the starting material for the thermoelectric conversion element, and sintering or the like subsequently may be carried out as described above. Also, for example, a starting material layer for the thermoelectric conversion element may be laminated onto a ferromagnetic material layer and/or a ferrimagnetic material layer or a layer of a starting material thereof, and sintered in an oxygen-containing atmosphere or in an inert atmosphere to obtain a thermoelectric conversion element containing the ferromagnetic material and/or the ferrimagnetic material layer.

b) Electrode-Forming Step

As shown in FIG. 1, the first electrodes 8 are formed on the first substrate 2 and the second electrodes 6 are formed on the second substrate 7. The first electrodes 8 and the second electrodes 6 may be formed on the main faces of the first substrate 2 and the second substrate 7, respectively, using, for example, a thin-film technique such as sputtering or vapor deposition, or a method such as screen printing, plating or thermal spraying.

c) Thermoelectric Conversion Element and Electrode Bonding Step

As shown in FIG. 1, the thermoelectric conversion elements 10 are positioned on the first electrodes 8 and the second electrodes 6 in a manner for proper placement of the obtained thermoelectric conversion elements 10. The thermoelectric conversion elements 10 are then placed on the first electrodes 8 and the second electrodes 6 and the thermoelectric conversion elements 10 are bonded with the electrodes 6, 8. The bonding is accomplished by electromagnetic induction heating. Specifically, for example, the thermoelectric conversion module 1 is set on the inner side of an induction coil 5 as shown in FIG. 1 prior to bonding of the thermoelectric conversion elements 10 and the electrodes 6, 8. When an alternating current is applied to the induction coil 5, the alternative magnetic field generated by the induction coil 5 is applied to the thermoelectric conversion elements 10 and the thermoelectric conversion elements 10 generate heat, thereby causing the surfaces of the first electrodes 6 and the second electrodes 8 being in contact with the thermoelectric conversion elements 10 (contact regions) are heated, whereby the thermoelectric conversion elements 10 become bonded with the first electrodes 8 and the second electrodes 6. The method of bonding by electromagnetic induction heating in this manner produces stronger bonding between the electrodes and the thermoelectric conversion elements, compared to methods of heating the thermoelectric conversion elements from the side of the substrate opposite the face on which the thermoelectric conversion elements are to be bonded, or methods of induction heating of the binder alone. Furthermore, direct induction heating of the thermoelectric conversion elements 10 themselves can reduce internally-generated residual stress and defects caused by the treatments of sintering, cutting, polishing and the like during the course of manufacturing of the thermoelectric conversion elements 10.

As the preferred conditions for bonding of the first electrodes 8 and the second electrodes 6 with the thermoelectric conversion elements 10 as shown in FIG. 1, the frequency of the alternating current flowing to the induction coil 5 is preferably about 10k−1 MHz, for example.

When the thermoelectric conversion elements 10 are bonded to the first electrodes 8 and the second electrodes 6, the thermoelectric conversion elements 10 are preferably subjected to electromagnetic induction heating until melting of the faces a1, b1 of the first electrodes 8 and the second electrodes 6 that are in contact with the thermoelectric conversion elements 10. When the faces of the first electrodes 8 and the second electrodes 6 being in contact with the thermoelectric conversion elements 10 (the contact regions) a1, b1 are heated to equal or above the melting point of the material composing the electrodes, more satisfactory adhesiveness is achieved between the electrodes and the thermoelectric conversion elements. Adjustment of the heating intensity can be accomplished, for example, by appropriately modifying the output and frequency from the induction coil 5, according to various conditions including the thermal conductivities of the materials of the substrates, the materials and sizes of the thermoelectric conversion elements, the melting point of the material composing the electrodes and the number of coils of the induction coil 5.

### Second Embodiment

### (Thermoelectric Conversion Module)

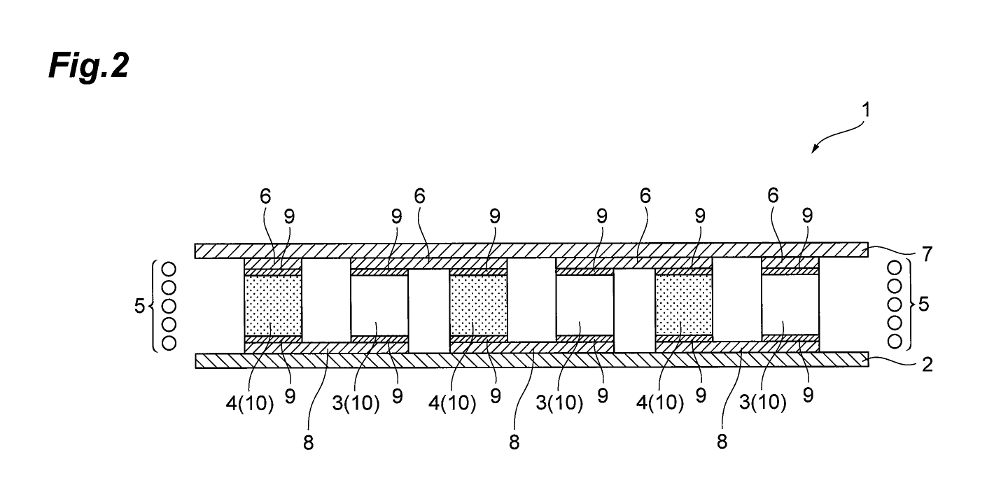

An example of a thermoelectric conversion module produced by a second embodiment will now be explained. FIG. 2 is a cross-sectional view of an example of the thermoelectric conversion module 1 produced by the second embodiment. The thermoelectric conversion module 1 produced in this embodiment is provided with a binder 9 between the thermoelectric conversion elements 10 and the first electrodes 8 and the second electrodes 6. The binder 9 bonds the thermoelectric conversion elements 10 with the first electrodes 8 and the second electrodes 6, with the plurality of thermoelectric conversion elements 10 being electrically connected in series. The binder 9 may be, for example, AuSb- or PbSb-based solder, or silver paste. The binder is preferably a solid during use of the thermoelectric conversion module.

### (Method for Manufacturing Thermoelectric Conversion Module)

In the method for manufacturing a thermoelectric conversion module of this embodiment, the binder 9 may be formed beforehand on the surfaces of the first electrodes 8 and the second electrodes 6 or on the surfaces of the thermoelectric conversion elements 10, the surfaces facing the electrodes 6, 8, before the step of bonding the electrodes to the thermoelectric conversion elements in the manufacturing method of the first embodiment, using a thin-film technique such as sputtering or vapor deposition or a method such as screen printing, plating or thermal spraying.

Also, the thermoelectric conversion elements 10 may be subjected to electromagnetic induction heating until melting of the binder 9, for bonding between the thermoelectric conversion elements 10 and the binder 9 as well as between the binder 9 and the first electrodes 8 and the second electrodes 6. The heating of the thermoelectric conversion elements until melting of the binder 9 results in bonding, by the binder, the electrodes to the thermoelectric conversion elements with high adhesiveness therebetween.

### Third Embodiment

### (Thermoelectric Conversion Module)

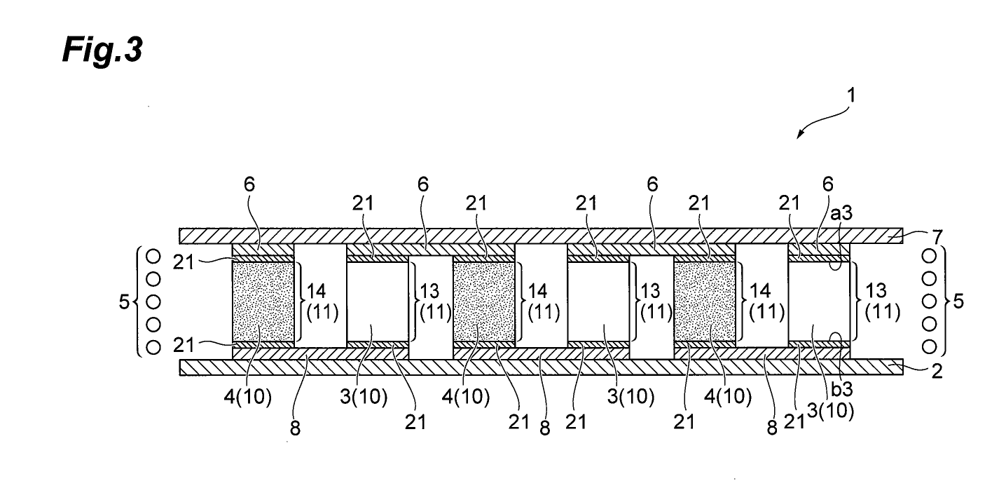

An example of a thermoelectric conversion module produced by a third embodiment will now be explained. FIG. 3 is a cross-sectional view of an example of the thermoelectric conversion module 1 produced by the third embodiment. A plurality of p-type thermoelectric conversion elements 13 and a plurality of n-type thermoelectric conversion elements 14 are alternately situated between the upper and lower opposing first substrate 2 and second substrate 7. The p-type thermoelectric conversion elements 13 and the n-type thermoelectric conversion elements 14 in the thermoelectric conversion module produced by this embodiment have metal (metalized) layers 21 on the top faces and bottom faces of the p-type thermoelectric conversion element bodies 3 and the n-type thermoelectric conversion element bodies 4. The metal layers 21 are provided to increase adhesion between the binder 9 and the thermoelectric conversion elements 10.

The material of the metal layers 21 is not particularly restricted so long as it is a metal or an alloy, and examples include silver, copper, iron, nickel, manganese and their alloys. The metal layers 21 also preferably contain a ferromagnetic material and/or a ferrimagnetic material, mentioned above.

### (Method for Manufacturing Thermoelectric Conversion Module)

In the method for manufacturing a thermoelectric conversion module of this embodiment, the metal layers 21 may be formed beforehand on the surfaces of the thermoelectric conversion elements 10, the surfaces facing the electrodes 6, 8, before the step of bonding the electrodes to the thermoelectric conversion elements in the manufacturing method of the first embodiment.

The method of forming the metal layers 21 may be, for example, dispersion of a metal compound whose main component is a compound which decomposes upon heating to generate a metal, onto the surfaces of the bodies of the thermoelectric conversion elements 10 that have been heated to above the decomposition temperature of the compound. Since the metal layers 21 formed by this method have high adhesiveness for the thermoelectric conversion element bodies 10, the bonding strength between the thermoelectric conversion element bodies 10 and the metal layers 21 is increased while the contact resistance between the bodies of the thermoelectric conversion elements 10 and the metal layers 21 is reduced.

There are no particular restrictions on the metal compound whose main component is a compound that produces a metal when decomposed by heat. The temperature that produces a metal when decomposed by heat is preferably a compound that produces a metal when decomposed at below the melting point or sublimation point of the compound. From the viewpoint of adhesiveness between the thermoelectric conversion elements 10 and the metal layers 21, the compound that produces a metal when decomposed by heat is preferably a silver compound, and more preferably Ag₂O or Ag₂CO₃. The compound may also be a metal oxide or metal carbonate, and is preferably at least one compound selected from the group consisting of MnO₃, FeCO₃, Cu₂CO₃, NiCO₃ and MnCO₃. This will allow formation of a film of silver, copper, iron, nickel, manganese or an alloy thereof. Particularly films of iron or cobalt are preferred, since they are ferromagnetic materials capable of electromagnetic induction heating.

When the compound that produces a metal when decomposed by heat does not produce a ferromagnetic material or a ferrimagnetic material, it is preferred to add one of the ferromagnetic materials and/or the ferrimagnetic materials mentioned for the first embodiment to the compound that produces a metal when decomposed by heat. A metal produced by decomposition of such a mixture is preferred because it has ferromagnetism or ferrimagnetism.

Considering that thermoelectric conversion modules may be used at temperatures of 300° C. and higher, oxides are preferred as ferromagnetic materials and/or ferrimagnetic materials to be present in the metal layer, from the viewpoint of heat resistance and oxidation resistance.

When the metal layers 21 contain an oxide ferromagnetic material and/or an oxide ferrimagnetic material, the content of the oxide ferromagnetic material and/or the oxide ferrimagnetic material is preferably 10-50 wt % based on the entire metal layer.

The method of forming the metal layers 21 is not limited to the method described above. For example, a desired metal layer or a metal layer containing a ferromagnetic material and/or a ferrimagnetic material may be formed on the bonding area with the electrode on the surface of the thermoelectric conversion element body, by plating, thermal spraying, vapor deposition, discharge plasma sintering or the like.

Even when the thermoelectric conversion elements 11 are provided with the aforementioned metal layers 21 on the surfaces of the thermoelectric conversion element bodies 10, as shown in FIG. 3, the thermoelectric conversion element bodies 10 can be directly heated by electromagnetic induction heating, so that the metal layers 21 and the electrodes 6, 8 are heated to allow bonding between the thermoelectric conversion elements 11 and the electrodes 6, 8. Also, it is convenient for the metal layers 21 to contain a ferromagnetic material and/or a ferrimagnetic material, as it will be possible to directly heat the metal layers 21. The electromagnetic induction heating is preferably carried out until melting of the surfaces of the metal layers 21 and the electrodes 7, 8. This will produce stronger adhesiveness between the thermoelectric conversion elements 11 and the first electrodes 8 and the second electrodes 6. Incidentally, even when a binder 9 lies between the thermoelectric conversion elements 11 and the first electrodes 8 and the second electrodes 6, the binder 9 can be adequately melted by electromagnetic induction heating in the same manner, thus allowing even stronger adhesiveness to be obtained between the thermoelectric conversion elements 11 and the first electrodes 8 and the second electrodes 6.

The method for manufacturing a thermoelectric conversion module according to the invention, and a thermoelectric conversion module produced by the manufacturing method, are not limited to the embodiments described above, and many modified forms thereof are possible. For example, the module may be a “skeleton-type” thermoelectric conversion module without the pair of mutually opposing substrates 2,7 of the thermoelectric conversion modules 1 illustrated in FIGS. 1 to 3, and instead comprising a support frame lying between the plurality of thermoelectric conversion elements 10 and holding and surrounding the centers of the thermoelectric conversion elements 10 in their height directions, to anchor each of the thermoelectric conversion elements at appropriate positions.

### EXPLANATION OF SYMBOLS

1: Thermoelectric conversion module, 2: first substrate, 3,13: p-type thermoelectric conversion elements, 4,14: n-type thermoelectric conversion elements, 6: second electrode, 7: second substrate, 8: first electrode, 9: binder, 10,11: thermoelectric conversion elements, a1,a3: surfaces of first electrodes 8 facing thermoelectric conversion elements, b1,b3: surfaces of second electrodes 6 facing thermoelectric conversion elements.

1. A method for manufacturing a thermoelectric conversion module, comprising a step of bonding a thermoelectric conversion element to an electrode by electromagnetic induction heating of the thermoelectric conversion element.

2. The method for manufacturing a thermoelectric conversion module according to claim 1, wherein the thermoelectric conversion element contains a ferromagnetic material and/or a ferrimagnetic material.

3. The method for manufacturing a thermoelectric conversion module according to claim 1, wherein the thermoelectric conversion element is subjected to electromagnetic induction heating with the thermoelectric conversion element being in contact with the electrode, until a contact region melts in which the surface of the electrode is in contact with the thermoelectric conversion element.

4. The method for manufacturing a thermoelectric conversion module according to claim 1, wherein the thermoelectric conversion element and the electrode are bonded to each other by a binder by electromagnetic induction heating the thermoelectric conversion element with the binder interposed between the thermoelectric conversion element and the electrode.

5. The method for manufacturing a thermoelectric conversion module according to claim 1, wherein the thermoelectric conversion element has a metal layer on a face of the surface of the thermoelectric conversion element, the face facing the electrode, and the metal layer contains a ferromagnetic material and/or a ferrimagnetic material.

6. The method for manufacturing a thermoelectric conversion module according to claim 2, wherein the thermoelectric conversion element is subjected to electromagnetic induction heating with the thermoelectric conversion element being in contact with the electrode, until a contact region melts in which the surface of the electrode is in contact with the thermoelectric conversion element.

7. The method for manufacturing a thermoelectric conversion module according to claim 2, wherein the thermoelectric conversion element and the electrode are bonded to each other by a binder by electromagnetic induction heating the thermoelectric conversion element with the binder interposed between the thermoelectric conversion element and the electrode.)
